(19) United States
(12) Patent Application Publication
(10) Pub. No.: US 2004/0206306 A1
(43) Pub. Date: Oct. 21, 2004

(54) DEPOSITION STATION FOR FORMING A POLYSILICON FILM OF LOW TEMPERATURE PROCESSED POLYSILICON THIN FILM TRANSISTOR

(76) Inventor: FRANK LIN, HSINCHU (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,536

(22) Filed: Apr. 17, 2003

(51) Int. Cl. C23C 16/00

(52) U.S. Cl. 118/719

(57) ABSTRACT

A deposition station of the invention comprises a chemical vapor deposition (CVD) chamber, a physical vapor deposition (PVD) chamber, at least a loadlock chamber, and a transfer chamber connected to the CVD and PVD chambers and the loadlock chamber. A vacuum is kept in the transfer chamber. To form a polysilicon film, a substrate is placed in the loadlock chamber, transits through the transfer chamber, and passes in the CVD chamber to form a buffer layer. After the formation of the buffer layer is completed, the substrate transits through the transfer chamber and passes in the PVD chamber to form an amorphous silicon film over the buffer layer. Once the PVD process is achieved, the substrate transits through the transfer chamber and passes in the loadlock chamber to be finally retrieved from the deposition station for other subsequent processing steps.

### BACKGROUND OF INVENTION

1. Field of the Invention

The invention relates generally to a semiconductor processing station and, more particularly, to a deposition station of cluster-tool type for fabricating a low temperature processed polysilicon thin film transistor.

2. Description of the Related Art

The applications of thin film transistors (TFT) are numerous, particularly in liquid crystal display (LCD) devices. LCD devices are known for their advantageous low operating voltages, absence of radiation, light weight, and smaller dimensional size. As electronic appliances increasingly become portable and smaller, the use of TFT-LCD devices is becoming more and more incumbent.

A thin film transistor is conventionally fabricated via numerous semiconductor processing steps achieved on substrate. However, due to a constraint inherent to the material of the substrate, for example glass-based material, the thin film transistor usually has to be fabricated in a low temperature condition. This requisite constraint applies more particularly to the formation of a polysilicon film serving as a channel in the thin film transistor. That is the reason why the LCD thin film transistor is also commonly designated as a “low temperature processed polysilicon thin film transistor”.

According to a method known in the prior art, the polysilicon film of low temperature processed polysilicon thin film transistor is formed by first performing a plasma enhanced chemical vapor deposition (PECVD) on a substrate to form a buffer film. Subsequently, an amorphous silicon (—Si) film is formed over the buffer film. A baking process is performed to reduce the amount of hydrogen in the α —Si film, which prevents the occurrence of an ablation effect in the subsequent laser process. Through an excimer laser annealing, the α —Si film is finally dehydrogenated and turned to a polysilicon film.

Instead of CVD process, another method known in the prior art is the use of a physical vapor deposition (PVD) that, by sputtering, deposits a substantially hydrogen-free α —Si film over the substrate. Although the PVD process may reduce in substantial manner the amount of hydrogen in the α —Si film, which allows a higher process window of the subsequent excimer laser annealing, the formation of the buffer film via a PVD process does not provide a film of good quality. The component characteristics of the thin film transistor therefore may be negatively affected.

### SUMMARY OF INVENTION

An aspect of the invention is therefore to provide a deposition station that can form a substantially hydrogen-free amorphous silicon film along with a buffer film of good quality in the manufacture of a low temperature processed polysilicon thin film transistor.

Another aspect of the invention is to provide a deposition station that can reduce the process window of the excimer laser annealing in the manufacture of a low temperature processed polysilicon thin film transistor.

Furthermore, another aspect of the invention is to provide a deposition station that can ensure the interface characteristics between the buffer film and the amorphous silicon film.

Still another aspect of the invention is to provide a deposition station that can reduce the conveyance time of the substrate.

To accomplish the above and other objectives, a deposition station of the invention comprises a chemical vapor deposition (CVD) chamber, a physical vapor deposition (PVD) chamber, at least a loadlock chamber, and a transfer chamber connected to the CVD and PVD chambers and the loadlock chamber. A vacuum is kept in the transfer chamber. To form a polysilicon film, a substrate is placed in the loadlock chamber, transits through the transfer chamber, and passes in the CVD chamber to form a buffer film. After the formation of the buffer film is completed, the substrate transits through the transfer chamber and passes in the PVD chamber to form an amorphous silicon film over the buffer film. Once the PVD process is achieved, the substrate transits through the transfer chamber and passes in the loadlock chamber to be finally retrieved from the deposition station for other subsequent processing steps.

Furthermore, a buffer chamber may be additionally connected between the PVD chamber and the transfer chamber to buffer a pressure difference between the CVD chamber and the PVD chamber.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a general schematic view of a first embodiment of the invention; and

FIG. 2 is a general schematic view of a second embodiment of the invention.

### DETAILED DESCRIPTION

The following detailed description of the embodiments and examples of the present invention with reference to the accompanying drawings is only illustrative and not limiting.

A major aspect of the invention is to provide a deposition station of cluster-tool type (i.e. multi-chambers) for forming a polysilicon film of low temperature processed polysilicon TFT that can integrate a chemical vapor deposition (CVD) chamber and a physical vapor deposition (PVD) chamber.

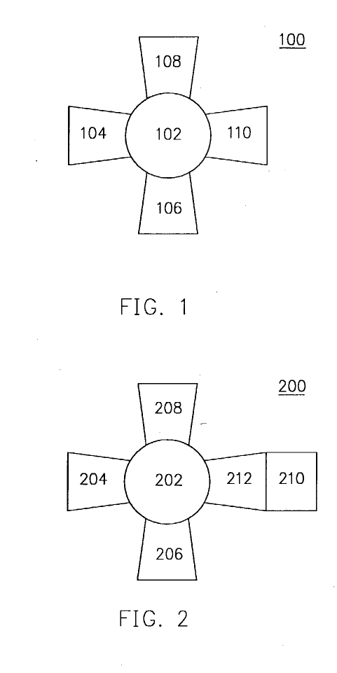

Referring to FIG. 1, a schematic view illustrates a cluster-tool type deposition station according to an embodiment of the invention. As illustrated, a cluster-tool deposition station 100 comprises a CVD chamber 108, a PVD chamber 110, a transfer chamber 102, and two loadlock chambers 104, 106. A vacuum is maintained in the transfer chamber 102 that is connected to the other chambers 104, 106, 108, 110. The CVD chamber 108 may be adapted to, for example, a plasma enhanced chemical vapor deposition (PECVD) process, in which case the pressure within the CVD chamber 108 has to be in a range of about 0.5 Torr to about 5 Torr. The PVD chamber 110 may be adapted to perform, for example, sputtering, in which case the pressure within the PVD chamber 110 has to be in a range of about 1 Torr to about 20 Torr. Once it has been placed in one loadlock chamber 108, a substrate transits through the transfer chamber 102 and passes into the CVD chamber 108 to be subjected to a CVD process for forming a buffer film. The buffer film can be, for example, either a stack film of silicon nitride and silicon oxide or a single film of silicon oxide. Once the CVD process within the CVD chamber 108 is completed, the substrate is retrieved via the transfer chamber 102 and is re-directed to the PVD chamber 110 to achieve another deposition process for forming an amorphous silicon layer (α —Si layer) over the buffer film. Once the PVD process is completed, the substrate passes through another loadlock chamber to be finally retrieved from the deposition station 100. An excimer laser annealing (ELA) then is performed to turn the amorphous silicon layer to a polysilicon film.

Instead of several loadlock chambers, the deposition station may be provided with a single loadlock chamber, in which case a conveyor tool (not shown) such as a mechanical arm should be further installed to achieve the placement and retrieval of the substrate.

Now referring to FIG. 2, a schematic view illustrates a deposition station for forming a polysilicon film according to a second embodiment of the invention. Similar to the first embodiment, a deposition station 200 of the second embodiment comprises a CVD chamber 208, a PVD chamber 210, a transfer chamber 202, and two loadlock chambers 204, 206. In addition, the deposition station 200 comprises a buffer chamber 212 that is arranged between the PVD chamber 210 and the transfer chamber 202. Besides the additional buffer chamber 212, the disposition of the other elements of the deposition station 200 is similar to that of the first embodiment. The purpose of the buffer chamber 212 is to buffer a pressure difference between the CVD chamber 208 (where the internal pressure is in a range of about 0.5 Torr to about 5 Torr) and the PVD chamber 210 (where the internal pressure is in a range of about 1 Torr to about 20 Torr).

As described above, the deposition station alternatively may be simply provided with a single loadlock chamber and an adequate conveyor tool such as a mechanical arm to achieve the conveyance of the substrate.

In conclusion, the invention as embodied above includes at least the advantages of enabling the formation of a good-quality buffer film along with the formation of a substantially hydrogen-free amorphous silicon film within a same deposition station. As a result, the substrate conveyance time is reduced and the process window of the subsequent excimer laser annealing is increased. Furthermore, via the vacuum of the transfer chamber between the CVD chamber 208 where the buffer film is formed and the PVD chamber 210 where the amorphous silicon film is formed, the interface characteristics between both buffer and amorphous silicon films can be therefore ensured.

It should be apparent to those skilled in the art that other structures that are obtained from various modifications and variations of different parts of the above-described structures of the invention would be possible without departing from the scope and spirit of the invention as illustrated herein. Therefore, the above description of embodiments and examples only illustrates specific ways of making and performing the invention that, consequently, should cover variations and modifications thereof, provided they fall within the inventive concepts as defined in the following claims.

1. A deposition station for manufacturing a low temperature processed polysilicon thin film transistor, comprising:
a chemical vapor deposition (CVD) chamber, where a substrate is subjected to the deposition of a buffer film;
a physical vapor deposition (PVD) chamber, where the substrate is subjected to a deposition of an amorphous silicon film;
a transfer chamber, connected between the CVD chamber and the PVD chamber, wherein the transit of the substrate between the CVD chamber and the PVD chamber is achieved via the transfer chamber; and
at least a loadlock chamber, connected to the transfer chamber, wherein the substrate is retrieved from and placed into the deposition station via the loadlock chamber.

2. The deposition station of claim 1, wherein the CVD chamber is a PECVD chamber.

3. The deposition station of claim 2, wherein an internal pressure of the PECVD chamber is in a range of about 0.5 Torr to about 5 Torr.

4. The deposition station of claim 1, wherein the PVD chamber is a sputtering chamber.

5. The deposition station of claim 4, wherein an internal pressure of the PVD chamber is in a range of about 1 Torr to about 20 Torr.

6. The deposition station of claim 1, wherein the transfer chamber is a vacuum chamber.

7. A deposition station for manufacturing a low temperature processed polysilicon thin film transistor, comprising:
a chemical vapor deposition (CVD) chamber, where a substrate is subjected to the deposition of a buffer film;
a physical vapor deposition (PVD) chamber, where a substrate is subjected to a deposition of an amorphous silicon film;
a buffer chamber, connected to the PVD chamber to buffer a pressure difference between an internal pressure of the PVD chamber and another pressure external to the PVD chamber;
at least a loadlock chamber, through which a substrate is retrieved from and placed into the deposition station; and
a transfer chamber, connected to the CVD chamber, the buffer chamber and the loadlock chamber, the transfer chamber having an internal vacuum through which the substrate transits from and to the PVD and CVD chambers.

8. The deposition station of claim 7, wherein the CVD chamber is a PECVD chamber.

9. The deposition station of claim 8, wherein an internal pressure of the PECVD chamber is in a range of about 1 Torr to about 20 Torr.

10. The deposition station of claim 7, wherein the PVD chamber is a sputtering chamber.

11. The deposition station of claim 10, wherein an internal pressure of the PVD chamber is in a range of about 1 Torr to about 20 Torr.
